(19) United States
(12) Patent Application Publication
(10) Pub. No.: US 2020/0333403 A1
(43) Pub. Date: Oct. 22, 2020

(54) POWER ELECTRONICS BASED RECONFIGURABLE LOAD TESTER

(71) Applicant: University of Tennessee Research Foundation, Knoxville, TN (US)

(72) Inventors: Fei Wang, Knoxville, TN (US); Zihan Gao, Knoxville, TN (US); Robert B. Martin, Knoxville, TN (US); Jiahao Niu, Knoxville, TN (US); Jingxin Wang, Knoxville, TN (US); Li Zhang, Knoxville, TN (US); Shiqi Ji, Knoxville, TN (US)

(21) Appl. No.: 16/743,047

(22) Filed: Jan. 15, 2020

Related U.S. Application Data
(60) Provisional application No. 62/836,622, filed on Apr. 20, 2019.

(51) Int. Cl. G01R 31/56

(52) U.S. Cl. CPC G01R 31/56

(57) ABSTRACT

Circuits and methods for testing power electronics devices. In some examples, a reconfigurable load tester includes a power conversion circuit configured to couple to a device under test (DUT). The power conversion circuit includes a number of arms, and each arm includes submodules. Each submodule includes one or more electronically-controlled switches. The reconfigurable load tester includes a controller configured for controlling the electronically-controlled switches of the submodules. The controller is configured for emulating, by controlling the electronically-controlled switches of the submodules, a plurality of electrical load levels/types on the DUT.

### PRIORITY CLAIM

This application claims the benefit of U.S. Provisional Patent Application Ser. No. 62/836,622, filed Apr. 20, 2019, the disclosure of which is incorporated herein by reference in its entirety.

### STATEMENT OF GOVERNMENT INTEREST

This invention was made with government support under Contract No. EEC1041877 awarded by the National Science Foundation. The government has certain rights in the invention.

### TECHNICAL FIELD

This specification relates generally to testing power electronics devices and in particular to reconfigurable load testers.

### BACKGROUND

Testing high voltage and high power equipment typically involves connecting a physical load or a power electronics load to a device under test (DUT) to test the DUT. A physical load has a fixed load type and offers only limited reconfiguration capability. Conventional power electronics loads offer only a fixed voltage/current rating and limited reconfiguration capability. Due to these limitations, testing different voltage and power ratings equipment may require connecting and disconnecting multiple loads to test the DUTs under various operating conditions.

### SUMMARY

This specification describes circuits and methods for testing power electronics devices. In some examples, a reconfigurable load tester includes a power conversion circuit configured to couple to a device under test (DUT). The power conversion circuit includes a number of arms, and each arm includes submodules. Each submodule includes one or more electronically-controlled switches. The reconfigurable load tester includes a controller configured for controlling the electronically-controlled switches of the submodules. The controller is configured for emulating, by controlling the electronically-controlled switches of the submodules, a plurality of electrical load levels and load types on the DUT.

In some examples, the power conversion circuit is a three phase alternating current (AC) power converter configured for converting AC power to DC power or DC power to AC power or both. The power conversion circuit can include three pairs of arms, and, for each pair of arms, a first arm is coupled between a positive voltage node of a DC link and an AC voltage node for one of the three phases of the AC power, and a second arm is coupled between the AC voltage node and a negative voltage node of the DC link.

The reconfigurable load tester can realize different voltage/current levels for load emulation. Compared to some conventional physical loads and power electronics loads, the reconfigurable load tester can be more flexible and more cost effective.

### BRIEF DESCRIPTION OF THE DRAWINGS

FIG. 1 is a block diagram of an example reconfigurable load tester;

FIG. 2 is a block diagram of an example power conversion circuit;

FIG. 3A is a block diagram of a first example arm of a power conversion circuit;

FIG. 3B is a block diagram of a second example arm of a power conversion circuit;

FIG. 3C is a circuit diagram of an example submodule;

FIG. 3D is a circuit diagram of a different example submodule; and

FIG. 4 is a block diagram of an example controller for the reconfigurable load tester.

### DETAILED DESCRIPTION

This specification describes circuits and methods for testing power electronics devices. In some examples, a reconfigurable load tester includes a power conversion circuit and a controller configured for emulating, by controlling submodules of the power conversion circuit, a plurality of electrical load levels and load types on the DUT. The reconfigurable load tester can realize different voltage/current levels for a number of different loads. Compared to some conventional physical loads and power electronics loads, the reconfigurable load tester can be more flexible and more cost effective.

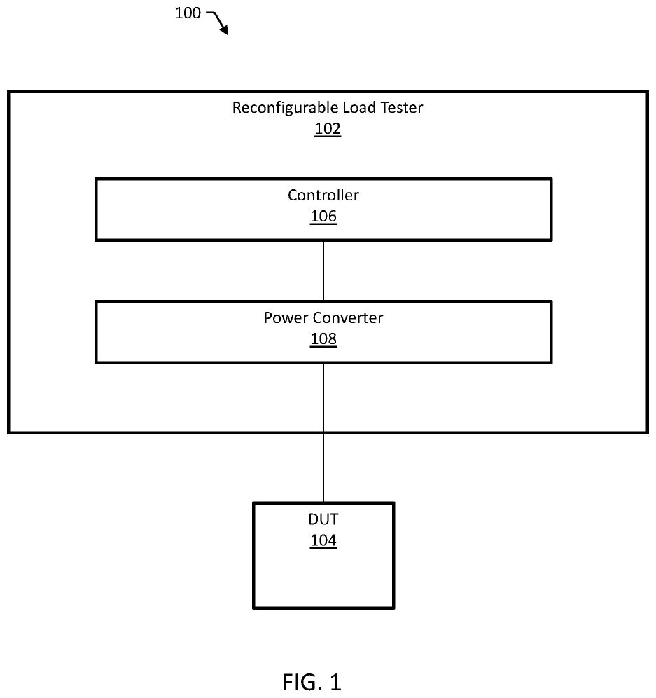

FIG. 1 is a block diagram of an example test environment 100 for a reconfigurable load tester 102. The reconfigurable load tester 102 is coupled to a DUT 104. The reconfigurable load tester includes a power conversion circuit 108 and a controller 106. The power conversion circuit 108 includes power electronics components that can be used to convert electric power from alternating current (AC) to direct current (DC), or vice versa.

The power conversion circuit 108, in this application, is used to test the DUT 104 by presenting different electrical load levels and types on the DUT 104. The controller 106 is configured for emulating various electrical load levels and types on the DUT 104 by controlling the power conversion circuit 108.

For example, an electrical load level can specify a target current, a target voltage, or a combination of current and voltage. An electrical load type can specify a target load voltage/current profile, e.g., an electric motor load. The controller 106 can select an electrical load level/type as part of testing the DUT 104 and then cause the power conversion circuit 108 to present the electrical load level/type to the DUT 104 by, e.g., controlling submodules of the power conversion circuit 108.

The DUT 104 may be any appropriate type of electrical device with different voltage and power ratings. Typically, the DUT 104 is a high voltage/high power electrical device. For example, the DUT 104 may include a transformer, high-voltage switchgear, or a power converter. In some examples, however, the DUT 104 is not a high voltage/high power electrical device. In general, the DUT 104 can be any appropriate electrical device to be tested.

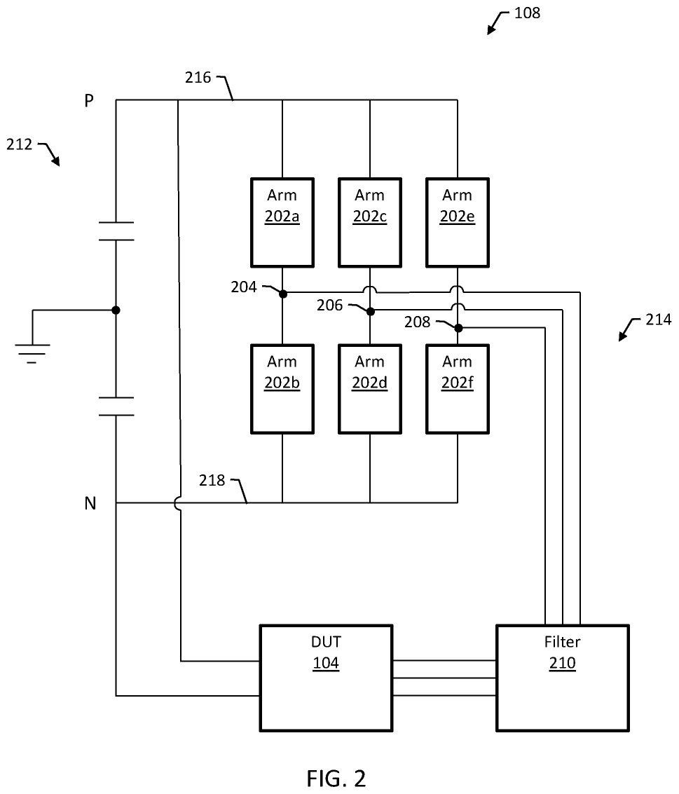

FIG. 2 is a block diagram of an example power conversion circuit 108 and electrical testing setup for the DUT 104. In this example, the DUT 104 shares a DC link 212 with the power conversion circuit 108. An output of the DUT 104 is coupled to a filter 210, and the output of the DUT 104 is coupled to the power conversion circuit 108 through the filter 210.

The power conversion circuit 108 is a three phase alternating current (AC) power converter configured for converting AC power to DC power or DC power to AC power or both. The power conversion circuit 108 includes three pairs of arms 202a-b, 202c-d, and 202e-f. Each pair of arms is coupled to one of three phases of an AC link 214 between the filter 210 and the power conversion circuit 108, and each pair of arms is coupled to the DC link 212.

For example, consider the first pair of arms 202a-b. The top arm 202a is coupled between a positive voltage node 216 of the DC link 212 and a first node 204 for a first phase of the AC link 214. The bottom arm 202b is coupled between the first node 204 for the first phase of the AC link 214 and a negative voltage node 218 of the DC link 212.

The second pair of arms 202c-d is connected similarly. The top arm 202c is coupled between the positive voltage node 216 of the DC link 212 and a second node 206 for a second phase of the AC link 214. The bottom arm 202d is coupled between the second node 206 for the second phase of the AC link 214 and the negative voltage node 218 of the DC link 212.

The third pair of arms 202e-f is connected similarly. The top arm 202e is coupled between the positive voltage node 216 of the DC link 212 and a third node 208 for a third phase of the AC link 214. The bottom arm 202f is coupled between the third node 208 for the third phase of the AC link 214 and the negative voltage node 218 of the DC link 212.

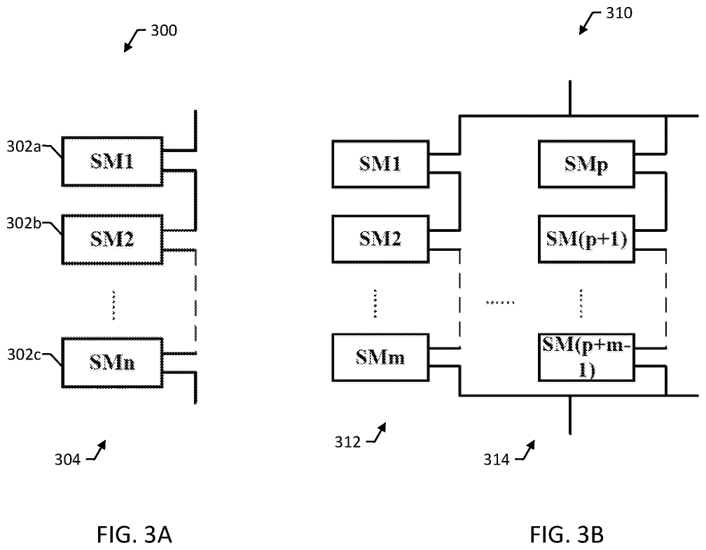

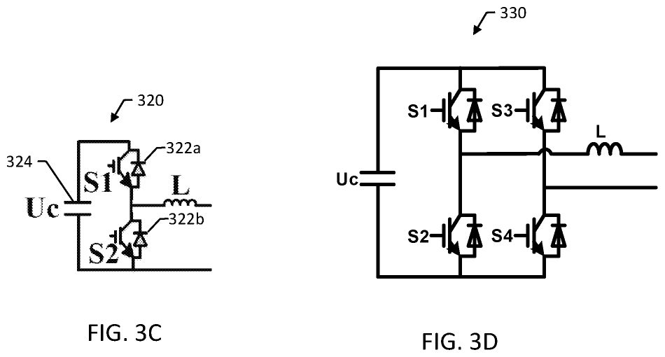

The arms 202a-f can each be individually configured with arrangements of submodules, or the arms 202a-f can each be made from an identical arrangement of submodules. FIGS. 3A-3B illustrate two examples of arrangements of submodules for the arms 202a-f.

FIG. 3A is a block diagram of a first example arm 300 of the power conversion circuit 108. The arm 300 includes submodules 302a-c connected in series to form a column 304 of submodules.

FIG. 3B is a block diagram of a second example arm 310 of the power conversion circuit 108. The arm 310 includes two or more columns 312 and 314 of submodules. Each of the columns 312 and 314 includes submodules connected in series. The columns 312 and 314 are connected to each other in parallel.

FIG. 3C is a circuit diagram of an example submodule 320. The submodule 320 includes a pair of transistors 322a-b, a capacitor 324, and an optional inductor L. The transistors 322a-b are coupled to the controller 106 and are electronically controllable by the controller 106. In operation, the controller 106 controls the submodules of the power conversion circuit 108 to form different voltage and/or current levels to emulate different types of loads in testing the DUT 104.

FIG. 3D is a circuit diagram of a different example submodule 330. The submodule 330 includes four transistors, a capacitor, and an optional inductor. In general, the reconfigurable load tester 102 can use any appropriate type of submodule, and the submodules 320 and 330 shown in FIGS. 3C and 3D are provided for purposes of illustration. Moreover, the submodules of the reconfigurable load tester 102 can all have the same circuit structure, or some of the submodules of the reconfigurable load tester 102 may be different from some other submodules of the reconfigurable load tester 102.

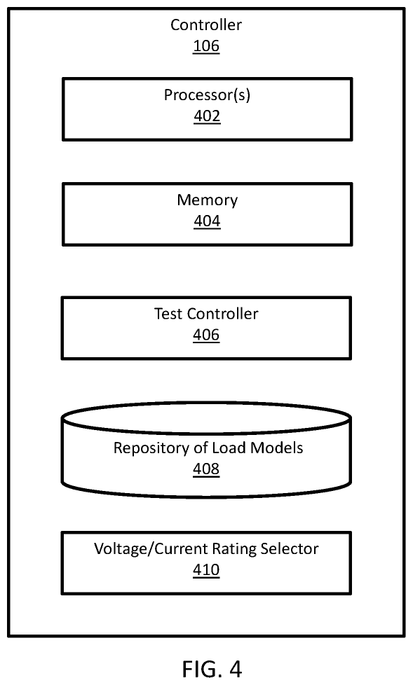

FIG. 4 is a block diagram of an example controller 106 for the reconfigurable load tester 102. The controller 106 has at least one processor 402 and memory 404 storing executable instructions for the processor 402. For example, the controller 106 may be implemented using a microcontroller, system on a chip, or any other appropriate computer system.

The controller 106 includes a test controller 406, a repository of load models 408, and voltage/current rating selector 410 implemented on the processor 402 and memory 404. The test controller 406 and the voltage/current rating selector 410 may be implemented, for example, as software executing on the processor 402. The repository of load models 408 may be implemented using any appropriate data structure.

The test controller 406 is configured to execute a test script for testing a DUT. Executing a test script can include, for example, receiving a user selection of a test script for a particular DUT, e.g., a particular type of power electronics device. Receiving a user selection can include presenting, on a display, a graphical user interface (GUI) displaying a list of available test scripts and receiving the user selection from a user input device.

Executing a test script can include selecting, by the voltage/current rating selector 410, a load model from the repository of load models 408 based on a voltage level selection or current level selection or both. The load model can specify, e.g., a configuration of a power conversion circuit. The configuration can be specified as instructions for controlling switches in arms of the power conversion circuit, and the configuration can be specified in any appropriate format or data structure.

The electrical load level/type selection can be specified, e.g., as part of the test script. Executing a test script can include controlling a power conversion circuit to emulate a load on the DUT as specified by the electrical load level/type selection and storing a result based on an output signal from the DUT in response to the electrical load level/type selection. Executing a test script can include repeatedly emulating electrical load levels/types and storing results for the different electrical load levels/types. Then, to complete, the test script, the controller can output a test result based on the stored results. For example, the controller can output a pass/fail message or a more detailed test report specifying the stored results or other test results based on the stored results. The controller can output the result, e.g., on a GUI or by sending data to an external computer system.

Although specific examples and features have been described above, these examples and features are not intended to limit the scope of the present disclosure, even where only a single example is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed in this specification (either explicitly or implicitly), or any generalization of features disclosed, whether or not such features or generalizations mitigate any or all of the problems described in this specification. Accordingly, new claims may be formulated during prosecution of this application (or an application claiming priority to this application) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A reconfigurable load tester comprising:
a power conversion circuit configured to couple to a device under test (DUT), the power conversion circuit comprising a plurality of arms, wherein each arm comprises a plurality of submodules each comprising one or more electronically-controlled switches; and
a controller configured for:
controlling the electronically-controlled switches of the submodules; and
emulating, by controlling the electronically-controlled switches of the submodules, a plurality of electrical load levels on the DUT.

2. The reconfigurable load tester of claim 1, wherein the power conversion circuit is an alternating current (AC) power converter configured for converting AC power to DC power or DC power to AC power or both.

3. The reconfigurable load tester of claim 2, wherein the power conversion circuit comprises a plurality pairs of arms.

4. The reconfigurable load tester of claim 3, wherein, for each pair of arms:
a first arm is coupled between a positive voltage node of a DC link and an AC voltage node for one phase of the AC power; and
a second arm is coupled between the AC voltage node and a negative voltage node of the DC link.

5. The reconfigurable load tester of claim 4, wherein the DUT shares the DC link with the power conversion circuit.

6. The reconfigurable load tester of claim 1, wherein the plurality of submodules for each arm are connected in series into a column of submodules.

7. The reconfigurable load tester of claim 1, wherein each arm comprises a plurality of columns of submodules, wherein each column of submodules comprises a plurality of submodules connected in series, and wherein the columns of submodules are connected in parallel.

8. The reconfigurable load tester of claim 1, wherein each submodule comprises different combinations of transistors and capacitors.

9. The reconfigurable load tester of claim 1, wherein the plurality of arms are coupled to an output of the DUT by a filter.

10. The reconfigurable load tester of claim 1, wherein the controller is configured for storing a plurality of load models for controlling the electronically-controlled switches.

11. The reconfigurable load tester of claim 10, wherein the controller is configured for selecting a load model based on a voltage level selection or current level selection or both.

12. The reconfigurable load tester of claim 1, wherein the controller is configured for outputting a test result based on an output signal from the DUT in response to emulating the plurality of electrical load levels.

13. A method for testing a device under test (DUT), the method comprising:
controlling a plurality of electronically-controlled switches of a power conversion circuit configured to couple to a device under test (DUT), the power conversion circuit comprising a plurality of arms, wherein each arm comprises a plurality of submodules each comprising one or more electronically-controlled switches; and
emulating, by controlling the electronically-controlled switches of the submodules, a plurality of electrical load levels on the DUT.

14. The method of claim 13, wherein the power conversion circuit is an alternating current (AC) power converter configured for converting AC power to DC power or DC power to AC power or both.

15. The method of claim 14, wherein the power conversion circuit comprises a plurality pairs of arms.

16. The method of claim 15, wherein, for each pair of arms:
a first arm is coupled between a positive voltage node of a DC link and an AC voltage node for one of the three phases of the AC power; and
a second arm is coupled between the AC voltage node and a negative voltage node of the DC link.

17. The method of claim 16, wherein the DUT shares the DC link with the power conversion circuit.

18. The method of claim 13, comprising storing a plurality of load models for controlling the electronically-controlled switches.

19. The method of claim 18, comprising selecting a load model based on a voltage level selection or current level selection or both.

20. The method of claim 13, comprising outputting a test result based on an output signal from the DUT in response to emulating the plurality of electrical load levels.
